(19) United States
(12) Patent Application Publication
(10) Pub. No.: US 2012/0262196 A1
(43) Pub. Date: Oct. 18, 2012

(54) SEMICONDUCTOR DEVICE INCLUDING PLURAL CORE CHIPS AND INTERFACE CHIP THAT CONTROLS THE CORE CHIPS AND CONTROL METHOD THEREOF

(75) Inventor: Hideyuki YOKOU, Tokyo (JP)

(73) Assignee: Elpida Memory, Inc., Tokyo (JP)

(21) Appl. No.: 13/439,726

(22) Filed: Apr. 4, 2012

(30) Foreign Application Priority Data
Apr. 18, 2011 (JP) 2011-091817

(51) Int. Cl. G01R 31/3187

(52) U.S. Cl. 324/750.3

(57) ABSTRACT

Disclosed herein is a device includes first and second core chips and a test circuit. The first core chip outputs an internal signal to a second node thereof in response to a core-chip test signal supplied to a first node thereof. The second core chip outputs an internal signal to a second node thereof in response to the core-chip test signal supplied to a first node thereof. The test circuit generates test result signals based on the internal signal of the first core chip being output from the second node of the first core chip, and the internal signal of the second core chip being output from the third node of the first core chip.

### BACKGROUND OF THE INVENTION

1. Field of the Invention

The present invention relates to a semiconductor device and a control method thereof, and more particularly to a semiconductor device including a plurality of core chips and an interface chip that controls these core chips and a control method thereof.

2. Description of the Related Art

A memory capacity that is required in a semiconductor memory device such as a DRAM (Dynamic Random Access Memory) is increasing every year. To satisfy this requirement, in recent years, a memory device that is called a multi-chip package where plural memory chips are laminated is suggested. However, since the memory chip used in the multi-chip package is a common memory chip capable of operating even though the memory chip is a single chip, a so-called front end unit that performs a function of an interface with an external device (memory controller, for example) is included in each memory chip. For this reason, the occupied area assignable for a memory core in each of the memory chips is limited to an area obtained by subtracting an occupied area for the front end unit from the whole chip area. Therefore, it is difficult to greatly increase a memory capacity for each chip.

In addition, a circuit that constitutes the front end unit is manufactured at the same time as a back end unit including a memory core, regardless of the circuit being a circuit of a logic system. Therefore there have been a further problem that it is difficult to speed up the front end unit.

As a method to resolve the above problem, a method that integrates the front end unit and the back end unit separately in discrete chips and laminates these chips, thereby constituting one semiconductor memory device, is suggested. According to this method, with respect to core chips in which the back end unit is integrated, it becomes possible to increase a memory capacity for each chip because an occupied area assignable for the memory core increases. Meanwhile, with respect to an interface chip that is integrated with the front end unit and is common to the plural core chips, it becomes possible to form its circuit with a high-speed transistor because the interface chip can be manufactured using a process different from that of the memory core. In addition, since the plural core chips can be allocated to one interface chip, it becomes possible to provide a semiconductor memory device that has a large memory capacity and a high operation speed as a whole.

In a semiconductor device using an interface chip, adjacent chips are electrically connected to each other by a large number of through silicon vias passing through substrates of core chips. Most of the through silicon vias are short-circuited to through silicon vias in other layers provided at same positions as seen in a planar view from a laminated direction. A current path for connecting the interface chip to each core chip is formed by a group of electrically short-circuited through silicon vias.

Japanese Patent Application Laid-open No. 2009-139273 discloses a testing technique for confirming a connection state of an internal terminal connecting a through silicon via to an internal circuit, although this is an example of a multi-chip package. According to the laminated configuration of this technique, internal terminals at the same position of a plurality of isomorphic memory core chips 2 are connected to each other via through silicon vias 4 with internal terminal junctions 3. These internal terminals are connected to an external terminal 5 by a wiring on an interposer chip 1 (not shown). The interposer chip 1 includes a unit that connects a wiring pattern to the external terminal 5 (for example, a through silicon via and a bonding pad (not shown)). This unit has a function to convert a position of the internal terminal with a position of the external terminal 5. That is, the external terminal 5 of the semiconductor device is electrically directly connected to any of the internal terminals that serve as a terminal to be measured in the semiconductor device. According to this testing technique, in the wiring configuration, a conduction check diode is provided in the midway of an internal wiring connecting the internal terminal to the internal circuit for each internal terminal, and its cathode side is connected to the internal wiring. A conduction test dedicated terminal is provided at an external terminal of a corresponding multi-chip package (a semiconductor device) for each memory chip and an anode of each conduction check diode within a same memory chip is commonly connected to the conduction test dedicated terminal. When the connection state of a certain internal terminal is tested, a voltage of −1 V is applied to a current path including the corresponding through silicon via through the external terminal and a voltage of 0 V is applied to the corresponding conduction test dedicated terminal. As a result, a forward current of the conduction check diode flows through the current path when the internal terminal is properly connected and the current does not flow when the internal terminal is disconnected. Therefore, by measuring the current appearing in the external terminal using a tester outside the semiconductor device, whether the internal terminal within the semiconductor device is properly connected can be determined.

Japanese Patent Application Laid-open No. H11-025699 discloses, as an example of a single chip package, a monitor that outputs an internal signal such as a sense-amplifier activation signal to outside during a test mode in a mold state.

A package of a conventional semiconductor device consisting of a single memory chip is configured in such a manner that circuits formed on an upper surface of the chip are exposed on the package surface. This configuration is adopted to easily perform an evaluation test of the semiconductor device with an external tester, and enables a monitor terminal of the external tester to be directly connected to the circuits or enables an electron beam to be directly applied to the circuits.

However, in a semiconductor device using one interface chip and a plurality of core chips, circuits of chips other than the uppermost chip (medium and lowermost chips stacked) cannot be exposed on the package surface. Therefore, the easy evaluation test as mentioned above cannot be performed and establishment of an alternative method has been needed.

Furthermore, even if the technique described in Japanese Patent Application Laid-open No. H11-025699 is applied to the semiconductor device having core chips stacked on one another, it is impossible to make plural internal signals respectively output from the core chips output to outside in parallel. For example, it is impossible to make plural internal signals of plural core chips that are manufactured with the same mask output separately to plural different nodes related to through silicon vias (TSV) included in the core chips, respectively. This is because, regarding the core chips manufactured with the same mask, an internal signal of a first core chip and an internal signal of a second core chip provoke a bus fight in the same nodes related to through silicon vias connected to each other. That is, when tests to observe the same internal nodes of the core chips are performed, the tests have to be performed serially for these internal nodes. Accordingly, plural test cycles are needed and thus test time increases. Even when the stacked core chips are manufactured with different masks and have different functions, outputting internal signals which are appeared in each of the plural different internal nodes of the plural core chips in serial to outside through plural test cycles causes an increase in test time.

### SUMMARY

In one embodiment, there is provided a semiconductor device that includes: first and second core chips stacked to each other, each of the first and second core chips having a control circuit that generates an internal signal; and a test circuit generating a core-chip test signal that is activated when the semiconductor device is in a test mode. The first core chip has first to third penetration electrodes penetrating through the first core chip. Each of the first and second core chips includes first to third nodes, the first to third nodes of the first core chip are arranged in substantially the same planar position as the first to third nodes of the second core chip, respectively. The first node of the first core chip and the first node of the second core chip are electrically connected to each other through the first penetration electrode. The second node of the first core chip and the third node of the second core chip are electrically connected to each other through the second penetration electrode. The third node of the first core chip and the second node of the second core chip are electrically connected to each other through the third penetration electrode. The test circuit supplies the core-chip test signal to the first node of the first core chip. The control circuit of the first core chip outputs the internal signal to the second node thereof in response to the core-chip test signal supplied to the first node thereof. The control circuit of the second core chip outputs the internal signal to the second node thereof in response to the core-chip test signal supplied to the first node thereof through the first penetration electrode. The test circuit generates test result signals based on the internal signal of the first core chip being output from the second node of the first core chip, and the internal signal of the second core chip being output from the third node of the first core chip.

In another embodiment, there is provided a semiconductor device that includes: an external terminal; an interface chip communicating with the external terminal; and first and second core chips being stacked to each other on the interface chip. Each of the first and second core chips includes first and second penetration electrodes penetrating therethrough. The first penetration electrode of the first core chip and the first penetration electrode of the second core chip are arranged at positions overlapped with each other as viewed from a stacking direction. The second penetration electrode of the first core chip and the second penetration electrode of the second core chip are arranged at positions overlapped with each other as viewed from the stacking direction. The first penetration electrode of the first core chip and the second penetration electrode of the second core chip are electrically connected to each other. The second penetration electrode of the first core chip and the first penetration electrode of the second core chip are electrically connected to each other. The interface chip includes a test circuit that activates a core-chip test signal when the semiconductor device is in a test mode, and an output circuit being electrically connected to the external terminal. Each of the first and second core chips outputs an internal signal that is generated in the corresponding core chip and is not output to outside in a normal mode, to the corresponding first through silicon via when the core-chip test signal is activated. The output circuit outputs a plurality of test result signals based on the internal signal of the first core chip being output from the first penetration electrode of the first core chip, and the internal signal of the second core chip being output from the second penetration electrode of the first core chip, to outside through the external terminal.

In still another embodiment, there is provided a control method of a semiconductor device that includes: entering into a test mode in response to a first command supplied from outside; activating a core-chip test signal in response to an entry to the test mode; supplying the core-chip test signal from an interface chip to first nodes of first and second core chips through a penetration electrode; supplying a plurality of internal signals from second nodes of the first and second core chips to the interface chip through a plurality of different penetration electrodes, respectively, in response to the core-chip test signal, the internal signals being not output to outside in a normal mode; and outputting the internal signals supplied through the different penetration electrodes to outside.

### BRIEF DESCRIPTION OF THE DRAWINGS

FIG. 1 is a schematic diagram for explaining an embodiment of the present invention;

FIG. 2 is a schematic cross-sectional view showing the structure of a semiconductor memory device 10 according to an embodiment of the present invention;

FIGS. 3A to 3C are diagram showing the various types of through silicon vias TSV provided in a core chip;

FIG. 4 is a cross-sectional view illustrating the structure of the through silicon via TSV1 of the type shown in FIG. 3A;

FIG. 5 is a block diagram illustrating the circuit configuration of the semiconductor memory device 10 shown in FIG. 2;

FIG. 6 is a circuit diagram showing only parts related to the test circuit configuration that enables evaluation tests of the core chips to be performed in parallel, out of the circuit configuration of the semiconductor device 10 shown in FIG. 5; and

FIG. 7 is a flowchart showing a process flow of the control method of the semiconductor device 10 shown in FIG. 5.

### DETAILED DESCRIPTION OF THE EMBODIMENTS

An embodiment of the present invention is described below. It is needless to mention that the contents that the present application is to claim for patent are not limited to the embodiment. That is, the present invention is applied to a semiconductor device that includes first and second core chips each generating an internal signal, and each of the first and second core chips includes second and third nodes spirally connected to the other core chips with through silicon vias and the internal signals to be observed are output through the second and third nodes. By observing the internal signals output in this way with an external tester or the like, evaluation tests of the core chips can be performed in parallel. Therefore, a simple evaluation test of the semiconductor device in short test time is realized. The evaluation tests in parallel can be performed simultaneously. Furthermore, the internal signals are not output to outside in a normal mode.

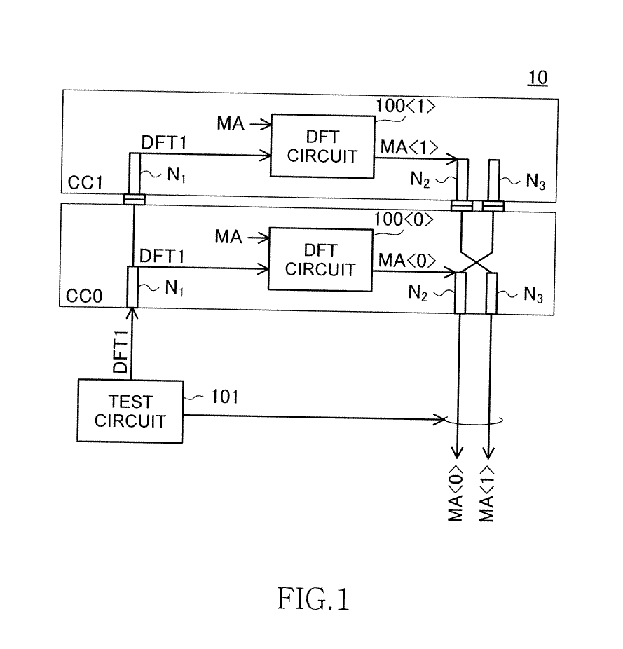

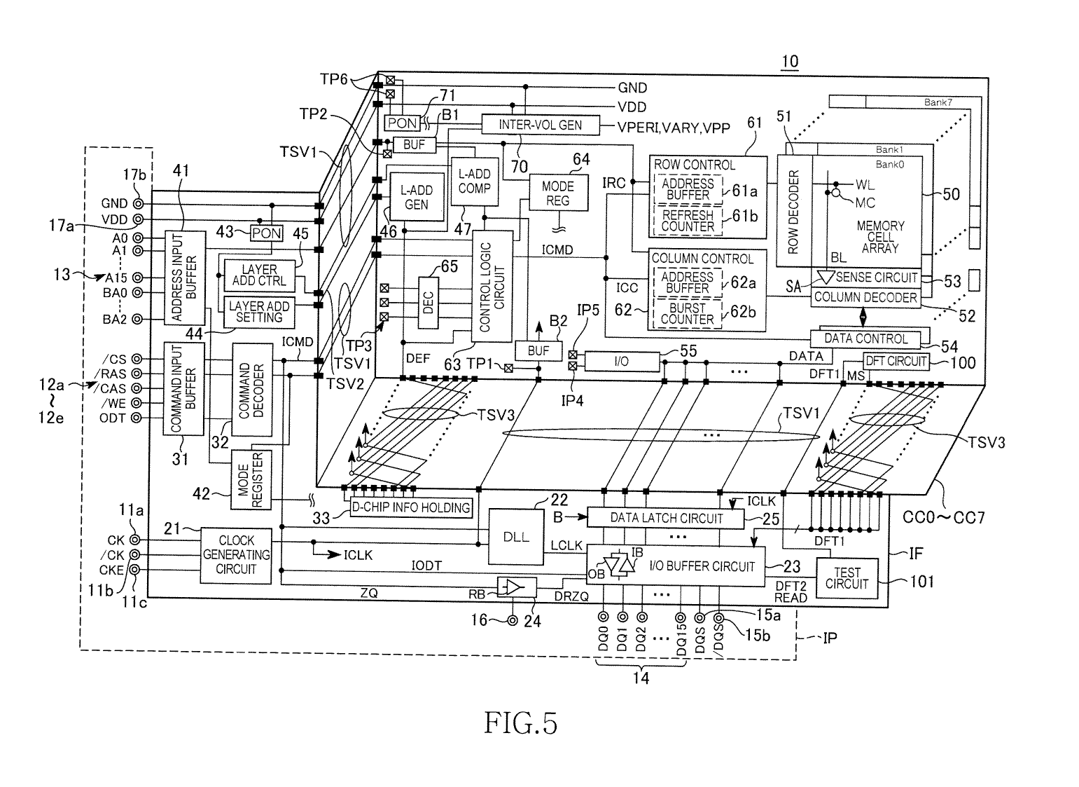

Referring now to FIG. 1, a semiconductor device 10 according to the embodiment includes first and second core chips CC0 and CC1 each of which generates an internal signal MA, and a test circuit 101 that generates a core-chip test signal DFT1 to be activated when the semiconductor device 10 enters into a test mode. The internal signal MA passes through various nodes (not shown) in the core chip. Specific examples thereof are those shown in FIG. 5, which will be explained below.

Each of the first and second core chips CC0 and CC1 has first to third nodes N₁ to N₃, and a DFT (Design For Testability) circuit 100 (control circuit). In drawings including FIG. 1 and explanations below, particularly when constituent elements of respective core chips need to be distinguished, the constituent elements are denoted by reference signs with angle brackets (< >). Numbers in the angle brackets (< >) correspond to serial numbers of the core chips.

As shown in FIG. 1, the first node N₁<0> included in the first core chip CC0 and the first node N₁<1> included in the second core chip CC1 are electrically connected to each other through a through silicon via that is formed through the second core chip CC1. The first nodes N₁ can be through silicon vias themselves and, in such cases, the first nodes N₁ of the core chips are arranged at positions overlapped with each other as viewed from a stacking direction. This is because various circuits explained below are lithographed on surfaces of the core chips, and the first nodes N₁ correspond to through silicon vias TSV1 explained below.

Meanwhile, the second node N₂<0> included in the first core chip CC0 is electrically connected to the third node N₃<1> included in the second core chip CC1 through a through silicon via that is formed through the second core chip CC1. Similarly, the third node N₃<0> included in the first core chip CC0 is electrically connected to the second node N₂<1> included in the second core chip CC1 through a through silicon via that is formed through the second core chip CC1. The second and third nodes N₂ and N₃ also can be through silicon vias themselves. The second nodes N₂ of the core chips are arranged at positions overlapped with each other as viewed from the stacking direction, and the third nodes N₃ of the core chips are arranged at positions overlapped with each other as viewed from the stacking direction. In short, the second and third nodes N₂ and N₃ are spirally connected, which correspond to through silicon vias TSV3 explained below.

The test circuit 101 supplies the generated core-chip test signal DFT1 to the first node N₁<0>. The test signal DFT1 thus supplied is supplied also to the first node N₁<1> through the through silicon via.

The DFT circuit 100<0> has a function to output the internal signal MA<0> to the second node N₂<0> in response to the test signal DFT1 supplied to the first node N₁<0>. Similarly, the DFT circuit 100<1> has a function to output the internal signal MA<1> to the second node N₂<1> in response to the test signal DFT1 supplied to the first node N₁<1>. Therefore, the internal signal MA<1> is supplied also to the third node N₃<0> through the through silicon via.

The test circuit 101 captures the internal signal MA<0> from the second node N₂<0> and the internal signal MA<1> from the third node N₃<0> and outputs the internal signals to outside.

With this configuration, the internal signals MA<0> and MA<1> corresponding to the first and second core chips CC0 and CC1, respectively, are output in parallel to outside of the semiconductor device 10. The internal signals MA<0> and MA<1> thus output are observed by a tester or the like, so that evaluation tests of the core chips can be performed in parallel.

Preferred embodiments of the present invention will be explained below in detail with reference to the accompanying drawings.

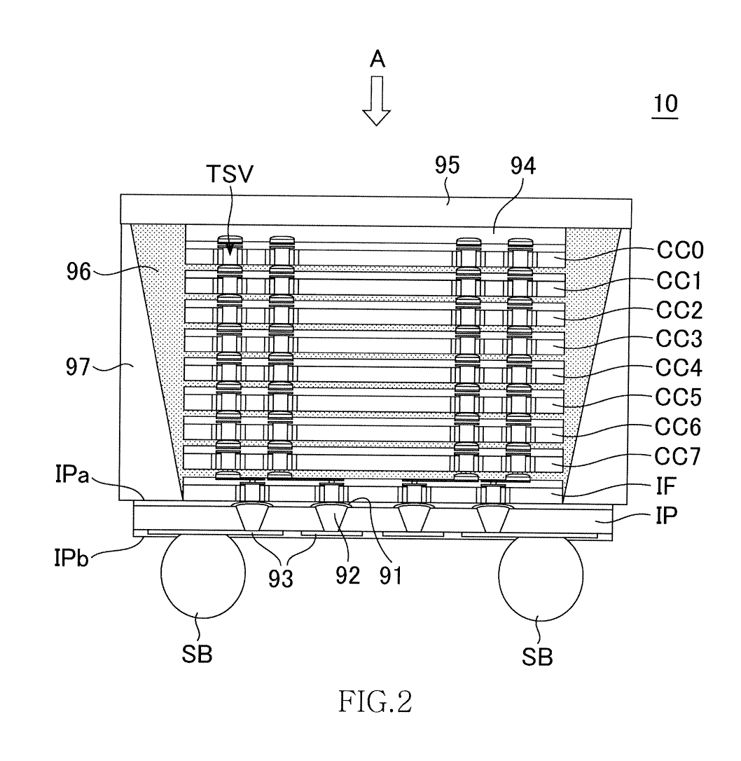

Turning to FIG. 2, the semiconductor device 10 according to this embodiment has the structure where eight core chips (memory chips) CC0 to CC7 and an interface chip IF are stacked on an interposer IP. The core chips CC0 to CC7 have the same function and structure as one another. It is worth noting that the uppermost core chip CC0 may have a different structure from the other core chips CC1 to CC7. For example, the uppermost core chip CC0 may be thicker than the remaining core chips CC1 to CC7. The core chips CC0 to CC7 are manufactured using the same manufacture mask whereas the interface chip IF is manufactured using a manufacture mask different from that of the core chips CC0 to CC7. The core chips CC0 to CC7 and the interface chip IF are semiconductor chips using a silicon substrate and are electrically connected to adjacent chips in a vertical direction through plural Through Silicon Vias (TSV) penetrating the silicon substrate. The through silicon via may be referred to as a penetration electrode. The uppermost core chip CC0 may not have the through silicon via TSV. Meanwhile, the interposer IP is a circuit board that is made of a resin, and plural external terminals (solder balls) SE are formed in a back surface IPb of the interposer IP.

Each of the core chips CC0 to CC7 is a semiconductor chip which consists of circuit blocks other than a so-called front end unit (front end function) performing a function of an interface with an external device through an external terminal among circuit blocks included in a 1 Gb DDR3 (Double Data Rate 3)-type SDRAM (Synchronous Dynamic Random Access Memory). The SDRAM is a well-known and common memory chip that includes both of the front end unit and a so-called back end unit having a plural memory cells and accessing to the memory cells. The SDRAM operates even as a single chip and is capable to communicate directly with a memory controller. That is, each of the core chips CC0 to CC7 is a semiconductor chip where only the circuit blocks belonging to the back end unit are integrated in principle. As the circuit blocks that are included in the front end unit, a parallel-serial converting circuit (data latch circuit) that performs parallel/serial conversion on input/output data between a memory cell array and a data input/output terminal and a DLL (Delay Locked Loop) circuit that controls input/output timing of data are exemplified, which will be described in detail below. The interface chip IF is a semiconductor chip in which only the front end unit is integrated. Accordingly, an operation frequency of the interface chip is higher than an operation frequency of the core chip. Since the circuits that belong to the front end unit are not included in the core chips CC0 to CC7, the core chips CC0 to CC7 cannot be operated as the single chips, except for when the core chips are operated in a wafer state for a test operation in the course of manufacturing the core chips. The interface chip IF is needed to operate the core chips CC0 to CC7. Accordingly, the memory integration of the core chips is denser than the memory integration of a general single chip. In the semiconductor memory device 10 according to this embodiment, the interface chip has a front end function for communicating with the external device at a first operation frequency, and the plural core chips have a back end function for communicating with only the interface chip at a second operation frequency lower than the first operation frequency. Accordingly, each of the plural core chips includes a memory cell array that stores plural information, and a bit number of plural read data for each I/O (DQ) that are supplied from the plural core chips to the interface chip in parallel is plural and associated with a one-time read command provided from the interface chip to the core chips. In this case, the plural bit number corresponds to a prefetch data number to be well-known.

The interface chip IF functions as a common front end unit (a processing circuit processing signals to communicate with the eight core chips CC0 to CC7 and a processing circuit processing signals from/to the external.) for the eight core chips CC0 to CC7. Accordingly, all external accesses are performed through the interface chip IF and inputs/outputs of data are also performed through the interface chip IF. In this embodiment, the interface chip IF is disposed between the interposer IP and the core chips CC0 to CC7. However, the position of the interface chip IF is not restricted in particular, and the interface chip IF may be disposed on the core chips CC0 to CC7 and may be disposed on the back surface IPb of the interposer IP. When the interface chip IF is disposed on the core chips CC0 to CC7 in a face-down manner or is disposed on the back surface IPb of the interposer IP in a face-up manner, the through silicon via TSV does not need to be provided in the interface chip IF. The interface chip IF may be disposed to be interposed between the two interposers IP.

The interposer IP functions as a rewiring substrate to increase an electrode pitch and secures mechanical strength of the semiconductor memory device 10. That is, an electrode 91 that is formed on a top surface IPa of the interposer IP is drawn to the back surface IPb via a through-hole electrode 92 and the pitch of the external terminals SB is enlarged by the rewiring layer 93 provided on the back surface IPb. In FIG. 1, only the two external terminals SB are shown. In actuality, however, three or more external terminals are provided. The layout of the external terminals SB is the same as that of the DDR3-type SDRAM that is determined by the regulation. Accordingly, the semiconductor memory device can be treated as one DDR3-type SDRAM from the external controller.

As shown in FIG. 2, a top surface of the uppermost core chip CC0 is covered by an NCF (Non-Conductive Film) 94 and a lead frame 95. Gaps between the core chips CC0 to CC7 and the interface chip IF are filled with an underfill 96 and surrounding portions of the gaps are covered by a sealing resin 97. Thereby, the individual chips are physically protected.

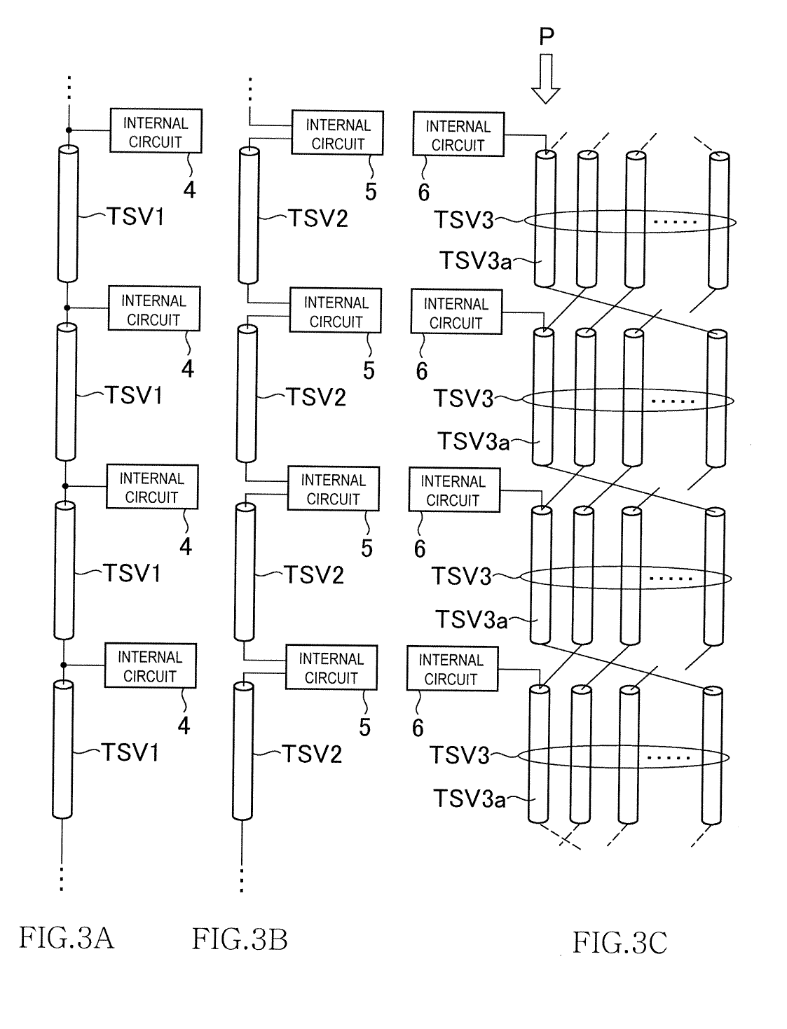

When most of the through silicon vias TSV provided in the core chips CC0 to CC7 are two-dimensionally viewed from a lamination direction, that is, viewed from an arrow A shown in FIG. 2, the through silicon vias TSV are short-circuited from the through silicon vias TSV of other layers provided at the same position. That is, as shown in FIG. 3A, the vertically disposed through silicon vias TSV1 that are provided at the same position in plan view are short-circuited, and one current path (an internal signal line) is configured by the through silicon vias TSV1. The through silicon vias TSV1 that are provided in the core chips CC0 to CC7 are connected to internal circuits 4 in the core chips, respectively. Accordingly, input signals (command signal, address signal, etc.) that are supplied from the interface chip IF to the through silicon vias TSV1 shown in FIG. 3A are commonly input to the internal circuits 4 of the core chips CC0 to CC7. Output signals (data etc.) that are supplied from the core chips CC0 to CC7 to the TSV1 are wired-ORed and input to the interface chip IF.

Meanwhile, as shown in FIG. 3B, the a part of through silicon vias TSV are not directly connected to the through silicon via TSV2 of other layers provided at the same position in plain view but are connected to the through silicon via TSV2 of other layers through the internal circuits provided in the core chips CC0 to CC7. That is, the internal circuits 5 that are provided in the core chips CC0 to CC7 are cascade-connected through the through silicon vias TSV2 and the current path (the internal signal line) configured by the through silicon vias TSV2 includes the internal circuits 5. This kind of through silicon vias TSV2 is used to sequentially transmit predetermined information to the internal circuits 5 provided in the core chips CC0 to CC7. As this information, layer address information to be described below is exemplified.

Another through silicon via TSV group is short-circuited from the through silicon via TSVs of other layer provided at the different position in plan view, as shown in FIG. 3C. With respect to this kind of through silicon via TSV 3, internal circuits 6 of the core chips CC0 to CC7 are connected to the TSV3a provided at the predetermined position P in plan view. Each of the current paths (the internal signal lines) configured by the through silicon vias TSV3 is connected to the internal circuit 6 provided in only one of the core chips, respectively. Thereby, information can be selectively input to the internal circuit 6 provided in each of the core chips. As this information, defective chip information described below is exemplified.

As such, as types of the through silicon vias TSV provided in the core chips CC0 to CC7, three types (TSV1 to TSV3) shown in FIGS. 3A to 3C exist. As described above, most of the through silicon vias TSV are of a type shown in FIG. 3A, and an address signal, a command signal, and a clock signal are supplied from the interface chip IF to the core chips CC0 to CC7, through the through silicon vias TSV1 of the type shown in FIG. 3A. Read data and write data are also input to and output from the interface chip IF through the through silicon vias TSV1 of the type shown in FIG. 3A. Meanwhile, the through silicon vias TSV2 and through silicon vias TSV3 of the types shown in FIGS. 3B and 3C are used to provide individual information to the core chips CC0 to CC7 having the same structure.

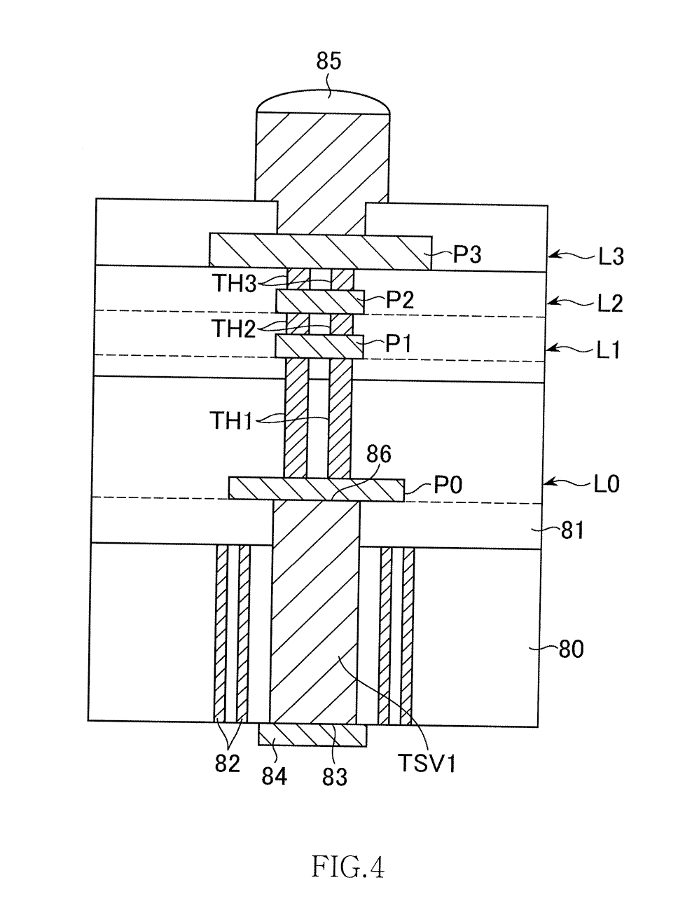

Turning to FIG. 4, the through silicon via TSV1 is provided to penetrate a silicon substrate 80 and an interlayer insulating film 81 provided on a surface of the silicon substrate 80. Around the through silicon via TSV1, an insulating ring 82 is provided. Thereby, the through silicon via TSV1 and a transistor region are insulated from each other. In an example shown in FIG. 4, the insulating ring 82 is provided double. Thereby, capacitance between the through silicon via TSV1 and the silicon substrate 80 is reduced.

An end 83 of the through silicon via TSV1 at the back surface of the silicon substrate 80 is covered by a back surface bump 84. The back surface bump 84 is an electrode that contacts a surface bump 85 provided in a core chip of a lower layer. The surface bump 85 is connected to an end 86 of the through silicon via TSV1, through plural pads P0 to P3 provided in wiring layers L0 to L3 and plural through-hole electrodes TH1 to TH3 connecting the pads to each other. Thereby, the surface bump 85 and the back surface bump 84 that are provided at the same position in plan view are short-circuited. Connection with internal circuits (not shown in the drawings) is performed through internal wiring lines (not shown in the drawings) drawn from the pads P0 to P3 provided in the wiring layers L0 to L3.

Turning to FIG. 5, the external terminals that are provided in the interposer IP include clock terminals 11a and 11b, an clock enable terminal 11c, command terminals 12a to 12e, an address terminal 13, a data input/output terminal 14, data strobe terminals 15a and 15b, a calibration terminal 16, and power supply terminals 17a and 17b. All of the external terminals are connected to the interface chip IF and are not directly connected to the core chips CC0 to CC7, except for the power supply terminals 17a and 17b.

First, a connection relationship between the external terminals and the interface chip IF performing the front end function and the circuit configuration of the interface chip IF will be described.

The clock terminals 11a and 11b are supplied with external clock signals CK and /CK, respectively, and the clock enable terminal 11c is supplied with a clock enable signal CKE. The external clock signals CK and /CK and the clock enable signal CKE are supplied to a clock generating circuit 21 provided in the interface chip IF. A signal where “/” is added to a head of a signal name in this specification indicates an inversion signal of a corresponding signal or a low-active signal. Accordingly, the external clock signals CK and /CK are complementary signals. The clock generating circuit 21 generates an internal clock signal ICLK, and the generated internal clock signal ICLK is supplied to various circuit blocks in the interface chip IF and is commonly supplied to the core chips CC0 to CC7 through the through silicon vias TSV.

A DLL circuit 22 is included in the interface chip IF and an input/output clock signal LCLK is generated by the DLL circuit 22. The input/output clock signal LCLK is supplied to an input/output buffer circuit 23 included in the interface chip IF. A DLL function is used to control the front end unit by using the signal LCLK synchronized with a signal of the external device, when the semiconductor memory device 10 communicates with the external device. Accordingly, DLL function is not needed for the core chips CC0 to CC7 as the back end.

The command terminals 12a to 12e are supplied with a row-address strobe signal /RAS, a column address strobe signal /CAS, a write enable signal /WE, a chip select signal /CS, and an on-die termination signal CDT. These command signals are supplied to a command input buffer 31 that is provided in the interface chip IF. The command signals supplied to the command input buffer 31 are further supplied to a command decoder 32. The command decoder 32 is a circuit that holds, decodes, and counts the command signals in synchronization with the internal clock ICLK and generates various internal commands ICMD. The generated internal command ICMD is supplied to the various circuit blocks in the interface chip IF and is commonly supplied to the core chips CC0 to CC7 through the through silicon vias TSV.

The address terminal 13 is a terminal to which address signals A0 to A15 and BA0 to BA2 are supplied, and the supplied address signals A0 to A15 and BA0 to BA2 are supplied to an address input buffer 41 provided in the interface chip IF. An output of the address input buffer 41 is commonly supplied to the core chips CC0 to CC7 through the through silicon vias TSV. The address signals A0 to A15 are supplied to a mode register 42 provided in the interface chip IF, when the semiconductor memory device 10 enters a mode register set. The address signals BA0 to BA2 (bank addresses) are decoded by an address decoder (not shown in the drawings) provided in the interface chip IF, and a bank selection signal B that is obtained by the decoding is supplied to a data latch circuit 25. This is because bank selection of the write data is performed in the interface chip IF.

The data input/output terminal 14 is used to input/output read data or write data DQ0 to DQ15. The data strobe terminals 15a and 15b are terminals that are used to input/output strobe signals DQS and /DQS. The data input/output terminal 14 and the data strobe terminals 15a and 15b are connected to the input/output buffer circuit 23 provided in the interface chip IF. The input/output buffer circuit 23 includes an input buffer IB and an output buffer OB, and inputs/outputs the read data or the write data DQ0 to DQ15 and the strobe signals DQS and /DQS in synchronization with the input/output clock signal LCLK supplied from the DLL circuit 22. If an internal on-die termination signal IODT is supplied from the command decoder 32, the input/output buffer circuit 23 causes the output buffer OB to function as a termination resistor. An impedance code DRZQ is supplied from the calibration circuit 24 to the input/output buffer circuit 23. Thereby, impedance of the output buffer OB is designated. The input/output buffer circuit 23 includes a well-known FIFO circuit.

The calibration circuit 24 includes a replica buffer RB that has the same circuit configuration as the output buffer OB. If the calibration signal ZQ is supplied from the command decoder 32, the calibration circuit 24 refers to a resistance value of an external resistor (not shown in the drawings) connected to the calibration terminal 16 and performs a calibration operation. The calibration operation is an operation for matching the impedance of the replica buffer RB with the resistance value of the external resistor, and the obtained impedance code DRZQ is supplied to the input/output buffer circuit 23. Thereby, the impedance of the output buffer OB is adjusted to a desired value.

The input/output buffer circuit 23 is connected to a data latch circuit 25. The data latch circuit 25 includes a FIFO circuit (not shown in the drawings) that realizes a FIFO function which operates by latency control realizing the well-known DDR function and a multiplexer MUX (not shown in the drawings). The input/output buffer circuit 23 converts parallel read data, which is supplied from the core chips CC0 to CC7, into serial read data, and converts serial write data, which is supplied from the input/output buffer, into parallel write data. Accordingly, the data latch circuit 25 and the input/output buffer circuit 23 are connected in serial and the data latch circuit 25 and the core chips CC0 to CC7 are connected in parallel. In this embodiment, each of the core chips CC0 to CC7 is the back end unit of the DDR3-type SDRAM and a prefetch number is 8 bits. The data latch circuit 25 and each banks of the core chips CC0 to CC7 are connected respectively, and the number of banks that are included in each of the core chips CC0 to CC7 is 8. Accordingly, connection of the data latch circuit 25 and the core chips CC0 to CC7 becomes 64 bits (8 bits×8 banks) for each DQ.

Parallel data, not converted into serial data, is basically transferred between the data latch circuit 25 and the core chips CC0 to CC7. That is, in a common SDRAM (in the SDRAM, a front end unit and a back end unit are constructed in one chip), between the outside of the chip and the SDRAM, data is input/output in serial (that is, the number of data input/output terminals is one for each DQ). However, in the core chips CC0 to CC7, an input/output of data between the interface chip IF and the core chips is performed in parallel. This point is the important difference between the common SDRAM and the core chips CC0 to CC7. However, all of the prefetched parallel data do not need to be input/output using the different through silicon vias TSV, and partial parallel/serial conversion may be performed in the core chips CC0 to CC7 and the number of through silicon vias TSV that are needed for each DQ may be reduced. For example, all of data of 64 bits for each DQ do not need to be input/output using the different through silicon vias TSV, and 2-bit parallel/serial conversion may be performed in the core chips CC0 to CC7 and the number of through silicon vias TSV that are needed for each DQ may be reduced to ½ (32).

To the data latch circuit 25, a function for enabling a test in an interface chip unit is added. The interface chip does not have the back end unit. For this reason, the interface chip cannot be operated as a single chip in principle. However, if the interface chip never operates as the single chip, an operation test of the interface chip in a wafer state may not be performed. This means that the semiconductor memory device 10 cannot be tested in case an assembly process of the interface chip and the plural core chips is not executed, and the interface chip is tested by testing the semiconductor memory device 10. In this case, when a defect that cannot be recovered exists in the interface chip, the entire semiconductor memory device 10 is not available. In consideration of this point, in this embodiment, a portion of a pseudo back end unit for a test is provided in the data latch circuit 25, and a simple memory function is enabled at the time of a test.

The power supply terminals 17a and 17b are terminals to which power supply potentials VDD and VSS are supplied, respectively. The power supply terminals 17a and 17b are connected to a power-on detecting circuit 43 provided in the interface chip IF and are also connected to the core chips CC0 to CC7 through the through silicon vias TSV. The power-on detecting circuit 43 detects the supply of power. On detecting the supply of power, the power-on detecting circuit activates a layer address control circuit 45 on the interface chip IF.

The layer address control circuit 45 changes a layer address due to the I/O configuration of the semiconductor device 10 according to the present embodiment. As described above, the semiconductor memory device 10 includes 16 data input/output terminals 14. Thereby, a maximum I/O number can be set to 16 bits (DQ0 to DQ15). However, the I/O number is not fixed to 16 bits and may be set to 8 bits (DQ0 to DQ7) or 4 bits (DQ0 to DQ3). The address allocation is changed according to the I/O number and the layer address is also changed. The layer address control circuit 45 changes the address allocation according to the I/O number and is commonly connected to the core chips CC0 to CC7 through the through silicon vias TSV.

The interface chip IF is also provided with a layer address setting circuit 44. The layer address setting circuit 44 is connected to the core chips CC0 to CC7 through the through silicon vias TSV. The layer address setting circuit 44 is cascade-connected to the layer address generating circuit 46 of the core chips CC0 to CC7 using the through silicon via TSV2 of the type shown in FIG. 3B, and reads out the layer addresses set to the core chips CC0 to CC7 at testing.

The interface chip IF is also provided with a defective chip information holding circuit 33. When a defective core chip that does not normally operates is discovered after an assembly, the defective chip information holding circuit 33 holds its chip number. The defective chip information holding circuit 33 is connected to the core chips CC0 to CC7 through the through silicon vias TSV. The defective chip information holding circuit 33 is connected to the core chips CC0 to CC7 while being shifted, using the through silicon via TSV3 of the type shown in FIG. 3C.

The interface chip IF also includes the test circuit 101. The test circuit 101 generates an interface-chip test signal DFT2 in addition to the core-chip test signal DFT1 mentioned above. The test circuit 101 is explained in detail later.

The above description is the outline of the connection relationship between the external terminals and the interface chip IF and the circuit configuration of the interface chip IF. Next, the circuit configuration of the core chips CC0 to CC7 will be described.

As shown in FIG. 5, memory cell arrays 50 that are included in the core chips CC0 to CC7 performing the back end function are divided into eight banks. A bank is a unit that can individually receive a command. That is, the individual banks can be independently and nonexclusively controlled. From the outside of the semiconductor memory device 10, each back can be independently accessed. For example, a part of the memory cell array 50 belonging to the bank 1 and another part of the memory cell array 50 belonging to the bank 2 are controlled nonexclusively. That is, word lines WL and bit lines BL corresponding to each banks respectively are independently accessed at same period by different commands one another. For example, while the bank 1 is maintained to be active (the word lines and the bit lines are controlled to be active), the bank 2 can be controlled to be active. However, the banks shares the external terminals (for example, plural control terminals and plural I/O terminals) of the semiconductor memory device 10. In the memory cell array 50, the plural word lines WL and the plural bit lines BL intersect each other, and memory cells MC are disposed at intersections thereof (in FIG. 5, only one word line WL, one bit line BL, and one memory cell MC are shown). The word line WL is selected by a row decoder 51. The bit line BL is connected to a corresponding sense amplifier SA in a sense circuit 53. The sense amplifier SA is selected by a column decoder 52.

The row decoder 51 is controlled by a row address supplied from a row control circuit 61. The row control circuit 61 includes an address buffer 61a that receives a row address supplied from the interface chip IF through the through silicon via TSV, and the row address that is buffered by the address buffer 61a is supplied to the row decoder 51. The address signal that is supplied through the through silicon via TSV is supplied to the row control circuit 61 through the input buffer B1. The row control circuit 61 also includes a refresh counter 61b. When a refresh signal is issued by a control logic circuit 63, a row address that is indicated by the refresh counter 61b is supplied to the row decoder 51.

The column decoder 52 is controlled by a column address supplied from a column control circuit 62. The column control circuit 62 includes an address buffer 62a that receives the column address supplied from the interface chip IF through the through silicon via TSV, and the column address that is buffered by the address buffer 62a is supplied to the column decoder 52. The column control circuit 62 also includes a burst counter 62b that counts the burst length.

The sense amplifier SA selected by the column decoder 52 is connected to the data control circuit 54 through some amplifiers (sub-amplifiers or data amplifiers, for example) which are not shown in the drawings. Thereby, read data of 8 bits (=prefetch number) for each I/O (DQ) is output from the data control circuit 54 at reading, and write data of 8 bits is input to the data control circuit 54 at writing. The data control circuit 54 and the interface chip IF are connected in parallel through the through silicon via TSV.

The control logic circuit 63 receives an internal command ICMD supplied from the interface chip IF through the through silicon via TSV and controls the row control circuit 61 and the column control circuit 62, based on the internal command ICMD. The control logic circuit 63 is connected to a layer address comparing circuit (chip information comparing circuit) 47. The layer address comparing circuit 47 detects whether the corresponding core chip is target of access, and the detection is performed by comparing a SEL (chip selection information) which is a part of the address signal supplied from the interface chip IF through the through silicon via TSV and a layer address LID (chip identification information) set to the layer address generating circuit 46.

In the layer address generating circuit 46, unique layer addresses are set to the core chips CC0 to CC7, respectively, at initialization. A method of setting the layer addresses is as follows. First, after the semiconductor memory device 10 is initialized, a minimum value (0, 0, 0) as an initial value is set to the layer address generating circuits 46 of the core chips CC0 to CC7. The layer address generating circuits 46 of the core chips CC0 to CC7 are cascade-connected using the through silicon vias TSV of the type shown in FIG. 2B, and have increment circuits provided therein. The layer address (0, 0, 0) that is set to the layer address generating circuit 46 of the core chip CC0 of the uppermost layer is transmitted to the layer address generating circuit 46 of the second core chip CC1 through the through silicon via TSV and is incremented. As a result, a different layer address (0, 0, 1) is generated. Hereinafter, in the same way as the above case, the generated layer addresses are transmitted to the core chips of the lower layers and the layer address generating circuits 46 in the core chips increment the transmitted layer addresses. A maximum value (1, 1, 1) as a layer address is set to the layer address generating circuit 46 of the core chip CC7 of the lowermost layer. Thereby, the unique layer addresses are set to the core chips CC0 to CC7, respectively.

The layer address generating circuit 46 is provided with a defective chip signal DEF supplied from the defective chip information holding circuit 33 of the interface chip IF, through the through silicon via TSV. As the defective chip signal DEF is supplied to the individual core chips CC0 to CC7 using the through silicon via TSV3 of the type shown in FIG. 3C, the defective chip signals DEF can be supplied to the core chips CC0 to CC7, individually. The defective chip signal DEF is activated when the corresponding core chip is a defective chip. When the defective chip signal DEF is activated, the layer address generating circuit 46 transmits, to the core chip of the lower layer, a non-incremented layer address, not an incremented layer address. The defective chip signal DEF is also supplied to the control logic circuit 63. When the defective chip signal DEF is activated, the control logic circuit 63 is completely halted. Thereby, the defective core chip performs neither read operation nor write operation, even though an address signal or a command signal is input from the interface chip IF.

An output of the control logic circuit 63 is also supplied to a mode register 64. When an output of the control logic circuit 63 shows a mode register set, the mode register 64 is updated by an address signal. Thereby, operation modes of the core chips CC0 to CC7 are set.

Each of the core chips CC0 to CC7 has an internal voltage generating circuit 70. The internal voltage generating circuit 70 is provided with power supply potentials VDD and VSS. The internal voltage generating circuit 70 receives these power supply potentials and generates various internal voltages. As the internal voltages that are generated by the internal voltage generating circuit 70, an internal voltage VPERI (=VDD) for operation power of various peripheral circuits, an internal voltage VARY (<VDD) for an array voltage of the memory cell array 50, and an internal voltage VPP (>VDD) for an activation potential of the word line WL are included. In each of the core chips CC0 to CC7, a power-on detecting circuit 71 is also provided. When the supply of power is detected, the power-on detecting circuit 71 resets various internal circuits.

The peripheral circuits in the core chips CC0 to CC7 operates in synchronization with the internal clock signal ICLK that is supplied form the interface chip IF through the through silicon via TSV. The internal clock signal ICLK supplied through the through silicon via TSV is supplied to the various peripheral circuits through the input buffer B2.

The above description is the basic circuit configuration of the core chips CC0 to CC7. In the core chips CC0 to CC7, the front end unit for an interface with the external device is not provided. Therefore the core chip cannot operate as a single chip in principle. However, if the core chip never operates as the single chip, an operation test of the core chip in a wafer state may not be performed. This means that the semiconductor memory device 10 cannot be tested, before the interface chip and the plural core chips are fully assembled. In other words, the individual core chips are tested when testing the semiconductor memory device 10. When unrecoverable defect exists in the core chips, the entire semiconductor memory device 10 is led to be unavailable. In this embodiment, in the core chips CC0 to CC7, a portion of a pseudo front end unit, for testing, that includes some test pads TP and a test front end unit of a test command decoder 65 is provided, and an address signal, a test data, or a command signal can be input from the test pads TP. It is noted that the test front end unit is provided for a simple test in a wafer test, and does not have all of the front end functions in the interface chip. For example, since an operation frequency of the core chips is lower than an operation frequency of the front end unit, the test front end unit can be simply realized with a circuit that performs a test with a low frequency.

The kind of the test pads TP is almost the same as those of the external terminals provided in the interposer IP. Specifically, the test pads TP include a test pad TP1 supplied with the clock signal, a test pad TP2 supplied with the address signal, test pads TP3 supplied with the command signal, a test pad TP4 for performing input/output of test data, a test pad TP5 for performing input/output of data strobe signal, test pads 6 for supplying power-supply voltages.

A common external command (not decoded) is input at testing. Therefore, the test command decoder 65 is also provided in each of the core chips CC0 to CC7. Because serial test data is input and output at testing, a test input/output circuit 55 is also provided in each of the core chips CC0 to CC7.

Each of the core chips CC0 to CC7 also includes the DFT circuit 100. The DFT circuit 100 is a circuit that outputs the internal signal of the corresponding core chip to the interface chip IF in response to the core-chip test signal DFT1 mentioned above. The DFT circuit 100 is also explained in detail later.

This is the entire configuration of the semiconductor memory device 10. Because in the semiconductor memory device 10, the 8 core chips of 1 GB are laminated, the semiconductor memory device 10 has a memory capacity of 8 GB in total. Because the chip selection signal /CS is input to one terminal (chip selection terminal), the semiconductor memory device is recognized as a single DRAM having the memory capacity of 8 GB, in view of the controller.

A test circuit configuration that enables evaluation tests of the core chips to be performed in parallel is explained below.

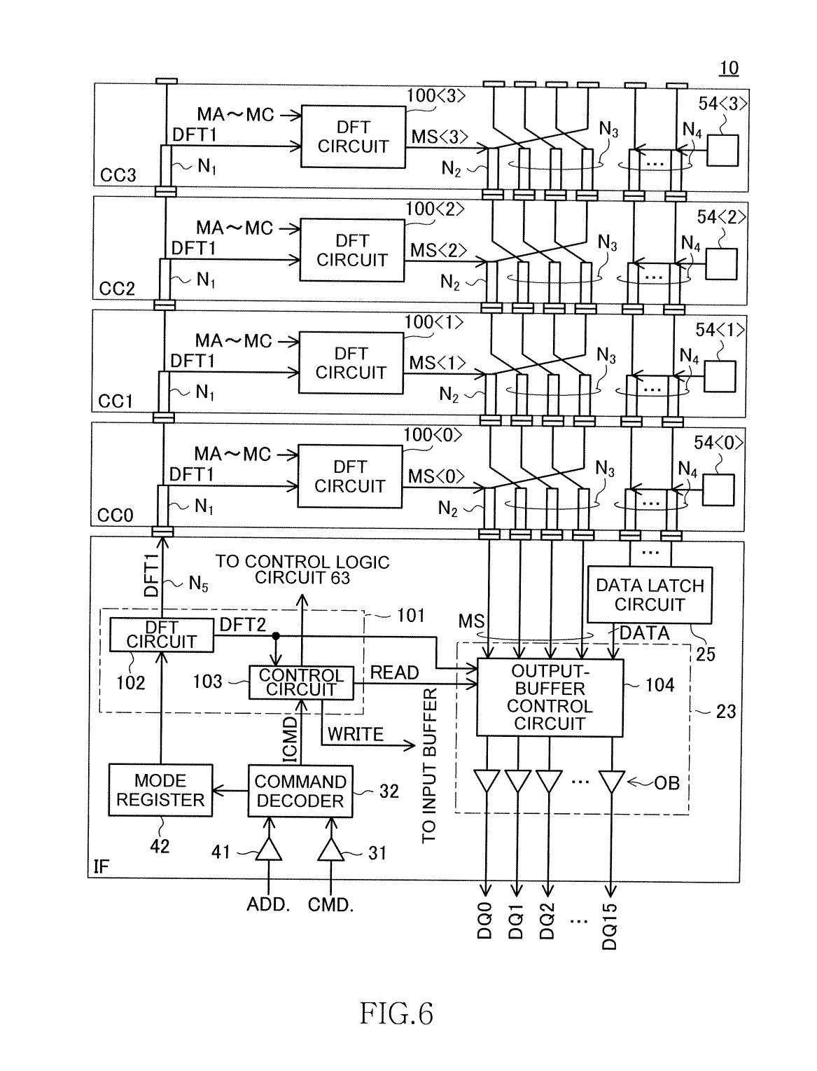

Turning to FIG. 6, the semiconductor device 10 according to the present embodiment includes the interface chip IF and the core chips CC0 to CC3. While the present embodiment is explained with an example including four core chips (CC0 to CC3), applicable targets of the present invention are not limited thereto and the present invention can be broadly applied to semiconductor devices having plural core chips. The present embodiment assumes that three internal signals MA to MC are to be tested. Each of the core chips CC0 to CC3 has a function to generate these three internal signals MA to MC.

The interface chip IF includes the input/output buffer circuit 23, the data latch circuit 25, the command input buffer 31, the command decoder 32, the address input buffer 41, the mode register 42, and the test circuit 101, as shown in FIG. 6. Among these circuits, the input/output buffer circuit 23 includes therein an output-buffer control circuit 104 (output circuit) and the output buffer OB, and the test circuit 101 includes therein a DFT circuit 102 and a control circuit 103.

Meanwhile, each of the core chips CC0 to CC3 includes first to fourth nodes N₁ to N₄, the data control circuit 54 (core output circuit), and the DFT circuit 100 (control circuit). One core chip includes one first node N₁, one second node N₂, three third nodes N₃, and a plurality of fourth nodes N₄. In explanations below, it is assumed that the first to fourth nodes N₁ to N₄ indicate through silicon vias themselves.

The first nodes N₁ constitute the through silicon vias TSV1 shown in FIG. 3A. That is, the first nodes N₅ are arranged at positions overlapped with each other as viewed from the stacking direction and the first nodes N₁ of adjacent chips are short-circuited with each other to constitute a current path. An end of the current path in the interface chip IF is electrically connected to an output node (a fifth node N₅) of the DFT circuit 102. Each of the first nodes N₁ is electrically connected to the DFT circuit 100 in the corresponding core chip.

The fourth nodes N₄ also constitute the through silicon vias TSV1 shown in FIG. 3A. Accordingly, a plurality of current paths from the uppermost core chip CC3 to the interface chip IF are formed. Each of the current paths is configured to include the number of (four, in this example) fourth nodes N₄ corresponding to the number of the core chips that are arranged at positions overlapped with each other as viewed from the stacking direction and are short-circuited with each other. An end of each current path in the interface chip IF is electrically connected to the data latch circuit 25. Each of the fourth nodes N₄ is electrically connected to the data control circuit 54 in the corresponding core chip.

On the other hand, the second and third nodes N₂ and N₃ constitute the through silicon vias TSV3 shown in FIG. 3C. The second node N₂ corresponds to the through silicon via TSV3a shown in FIG. 3C and is electrically connected to the OFT circuit 100 in each of the core chips. Accordingly, the number of (four, in this example) current paths corresponding to the number of the core chips are formed from the respective second nodes N₂ to the interface chip IF without a bus fight among the core chips. An end of each current path in the interface chip IF is electrically connected to the output-buffer control circuit 104.

Various commands are supplied from outside to the command decoder 32 through the external terminal SB shown in FIG. 2. The commands include a command (first command) directing an entry to a test mode, and a command (second command) directing an operation mode of the core chips such as a read command or a write command.

The command decoder 32 recognizes an entry to the test mode when the first command is supplied from outside. The command decoder 32 having recognized the entry to the test mode generates information indicating the entry to the test mode and stores the information in the mode register 42. When the second command is supplied from outside, the command decoder 32 generates an internal command ICMD indicating details of the supplied command and supplies the internal command ICMD to the control circuit 103.

The control circuit 103 supplies the internal command ICMD supplied from the command decoder 32 to the control logic circuit 63, and also supplies a write command WRITE to the input buffer IB when the second command is a write command. Accordingly, the core chips CC0 to CC3 are set to an operation mode according to the second command and generation of an internal signal to be observed is started in the core chips CC0 to CC3. When the test signal DFT2 explained later indicates that the semiconductor device 10 is in the test mode, the control circuit 103 generates a read command READ according to the internal command ICMD and supplies the read command READ to the output-buffer control circuit 104. Generation of the read command READ is performed regardless of the type of the internal command ICMD. The control circuit 103 performs this processing during the test mode to enable the internal signals of the core chips to be observed in any operation mode. Details thereof are explained later.

The DFT circuit 102 determines whether the semiconductor device 10 is in a test mode by checking the information stored in the mode register 42, and when it is determined that the semiconductor device 10 is in the test mode, the DFT circuit 102 activates the core-chip test signal DFT1 and the interface-chip test signal DFT2. The test signals DFT1 and DFT2 are both activated when the semiconductor device 10 has entered into the test mode and otherwise deactivated. In the present embodiment, the test signal DFT1 is a ⅓ select signal including first to third test signals DFT1, anyone of which is exclusively activated. The first to third test signals DFT1 correspond to the internal signals MA to MC, respectively. On the other hand, the test signal DFT2 is a ½ select signal indicating whether the semiconductor device 10 has entered into the test mode. The test signal DFT1 is supplied to the DFT circuit 100 of each of the core chips through the first node N₁ of the corresponding core chip. The test signal DFT2 is supplied to the control circuit 103 and the output-buffer control circuit 104.

When the test signal DFT1 is activated, the DFT circuit 100 of each core chip acquires one of the internal signals MA to MC corresponding to the activated test signal DFT1 and outputs the acquired internal signal as a monitor signal MS to the second node N₂. That is, for example, the DFT circuit 100 outputs the internal signal MA as the monitor signal MS when the first test signal DFT1 is activated, outputs the internal signal MB as the monitor signal MS when the second test signal DFT1 is activated, and outputs the internal signal MC as the monitor signal MS when the third test signal DFT1 is activated. The monitor signals MS thus supplied to the second nodes N₂ of the core chips are supplied in parallel to the output-buffer control circuit 104 in the interface chip IF through the second and third nodes N₂ and N₃ spirally connected.

The data latch circuit 25 acquires read data (a plurality of data signals DATA) output from the data control circuits 54 through the fourth nodes N₄ and outputs the read data to the output-buffer control circuit 104. This means that the plural monitor signals MS and the plural data signals DATA are supplied to the output-buffer control circuit 104.

The output-buffer control circuit 104 selects either the monitor signals MS or the data signals DATA according to the test signal DFT2. The output-buffer control circuit 104 then outputs the selected signals to outside of the semiconductor device 10 through the data input/output terminals 14. More specifically, the output-buffer control circuit 104 outputs the data signals DATA to outside during the normal operation (when it is not in a test mode), and outputs the monitor signals MS instead of the data signals DATA to outside in response to supply of the read command READ from the control circuit 103 (in response to supply of the second command from outside to the command decoder 32) when the test signal DFT2 is activated.

As described above, according to the present embodiment, the internal signals (the monitor signals MS) of the core chips can be output in parallel through the data input/output terminals 14 by causing the semiconductor device 10 to enter into the test mode. Therefore, the evaluation tests of the core chips can be performed in parallel by observing the output monitor signals MS with the external tester. Accordingly, a simple evaluation test of the semiconductor device is realized and also the test time is reduced.

Furthermore, because the control circuit 103 supplies the read command READ to the output-buffer control circuit 104 during the test mode regardless of the details of the internal command ICMD, the monitor signals MS can be output from the data input/output terminals 14 even in cases where no output from the data input/output terminals 14 is originally performed, such as during a write operation. Therefore, as well as the internal signals related to the read operation, the internal signals related to other operations such as the write operation can be also observed from outside.

It is preferable that output of the monitor signals MS is performed by exclusively using one of the data input/output terminals 14 with respect to each of the core chips. This is for enabling the monitor signals MS of the core chips to be observed in parallel. However, depending on the type of the external tester, the number of terminals of the external tester may be smaller than the number of core chips, which prevents parallel observation of all the core chips. In such cases, it is preferable to deselect core chips not to be observed by using the chip select information so as to bring outputs of the corresponding DFT circuits 100 into a high impedance state. This process is preferably performed by the layer-address comparison circuit 47.

A control method of the semiconductor device 10 according to the present embodiment is explained again in detail with reference to a process flow.

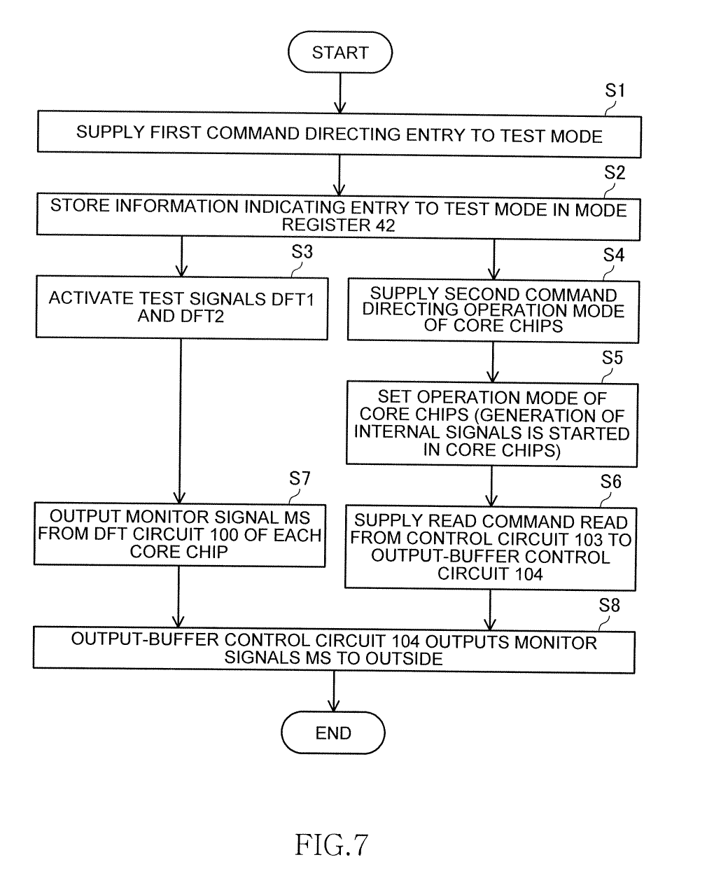

Turning to FIG. 7, in this control method, the first command directing an entry to a test mode is first supplied to the semiconductor device 10 through the external terminal SB (FIG. 2) (Step S1). In response thereto, information indicating the entry to the test mode is stored in the mode register 42 (Step S2).

When the semiconductor device 10 enters into the test mode, the DFT circuit 102 activates the test signals DFT1 and DFT2 (Step S3). The test signal DFT1 is supplied to the first nodes N₁ of the core chips and the test signal DFT2 is supplied to the output-buffer control circuit 104 and the control circuit 103.

In parallel to Step S3, the second command directing an operation mode of the core chips is supplied to the semiconductor device 10 through the external terminal SB (FIG. 2) (Step S4). Accordingly, the operation mode of the core chips is set and generation of internal signals to be observed is started in the core chips (Step S5). Furthermore, the read command READ is supplied from the control circuit 103 to the output-buffer control circuit 104 (Step S6). A process at Step S6 is performed to enable output of the monitor signals MS.

The DFT circuit 100 of each core chip having received the test signal DFT1 through the first node N₁ acquires the internal signal to be observed and outputs the internal signal as the monitor signal MS to the second node N₂ (Step S7).

Finally, the output-buffer control circuit 104 outputs the monitor signals MS, which have been output to the second nodes N2 of the core chips, to outside through the data input/output terminals 14 and the external terminals SB (Step S8). By the above-mentioned control, it becomes possible to make the semiconductor device 10 enter into the test mode and output the internal signals (monitor signals MS) of the core chips in parallel from the data input/output terminals 14.

It is apparent that the present invention is not limited to the above embodiments, but may be modified and changed without departing from the scope and spirit of the invention.

For example, while the core-chip test signal DFT1 is the ⅓ select signal including the three test signals DFT1 in the present embodiment, the core-chip test signal DFT1 can be a 1/n select signal including n (n is a natural number) test signals DFT1. It is appropriate that a specific value of n is the number of types of the internal signals to be observed.

While a group of the through silicon vias TSV transmitting the monitor signals MS is provided separately from a group of the through silicon vias TSV transmitting the defective chip information in FIG. 5, the same group of through silicon vias TSV can be used therefor.

Further, in the embodiment, the DDR3-type SDRAMs are used as the plural core chips having the same function. However, the present invention is not limited thereto. Accordingly, the core chip may be a DRAM other than the DDR3-type or a semiconductor memory (SRAM (Static Random Access Memory), PRAM (Phase-change Random Access Memory), MRAM (Magnetic Random Access Memory) or a flash memory, for example) other than the DRAM. The core chips may be plural semiconductor chips that have functions other than the functions of the semiconductor memory, which are equal to or different from each other. All of the core chips do not need to be laminated and all or part of the core chips may be two-dimensionally disposed. The number of core chips is not restricted to 8.

The fundamental technical concept of the present invention is not limited to that. For example, the core chips have been described as chips of semiconductor memories having the same function. However, the fundamental technical concept of the present invention is not limited to that, and the core chips may have the same function as one another or different functions from one another. Specifically, the interface chip and the core chips may be silicon chips each having a unique function. For example, the core chips may be DSP chips having the same function, and may have an interface chip (ASIC) shared among the core chips. Preferably, the core chips have the same function as one another, and are manufactured with the use of the same mask. However, the characteristics after the manufacture might vary due to the in-plane distribution in the same wafer, differences among wafers, differences among lots, and the likes. Further, the core chips each have a memory function, but may also have different functions from one another (a first core chip is a DRAM, a second chip is a SRAM, a third chip is a nonvolatile memory, and a fourth chip is a DSP). The core chips may be manufactured with the use of different manufacturing masks from one another, and may have an interface chip (ASIC) shared among the core chips.

The present invention may also be applied to all semiconductor products such as CPUs (Central Processing Units), MCUs (Micro Control Units), DSPs (Digital Signal Processors), ASICs (Application Specific Integrated Circuits), and ASSPs (Application Specific Standard Circuit), as long as they are COCs (Chip-on-Chips) that use TSVs. The devices to which the present invention is applied may also be used as the semiconductor devices in SOCs (System-on-Chips), MCPs (Multi Chip Packages), POPs (Package-On-Packages), and the likes. The transistors may be field effect transistors (FETs) or bipolar transistors. The present invention may be applied to various kinds of FETs such as MISs (Metal-Insulator Semiconductors) and TFTs (Thin Film Transistors), other than MOSs (Metal Oxide Semiconductors). The present invention may be applied to various kinds of FETs such as transistors. The transistors may be other transistors than FETs. The transistors may partially include bipolar transistors. Also, p-channel transistors or PMOS transistors are typical examples of the transistors of the first conductivity type, and n-channel transistors or NMOS transistors are typical examples of the transistors of the second conductivity type. Further, the substrate may not necessarily be a p-type semiconductor substrate, and may be an n-type semiconductor substrate, or a semiconductor substrate of a SOI (Silicon on Insulator) structure, or a semiconductor substrate of some other type.

Further, the circuit forms of various test circuits (such as current sources, current mirrors, sense amplifiers, compare amplifiers, selectors) are not limited to the circuit forms disclosed in the embodiments.

Further, the structures of TSVs are not particularly limited.

Various combinations and selections of the components disclosed herein may be made within the scope of the invention. In other words, the present invention of course includes various changes and modifications that are obvious to those skilled in the art according to all the disclosure including the claims and the technical concept.

What is claimed is:

1. A semiconductor device comprising:
first and second core chips stacked to each other, each of the first and second core chips having a control circuit that generates an internal signal; and
a test circuit generating a core-chip test signal that is activated when the semiconductor device is in a test mode, wherein
the first core chip has first to third penetration electrodes penetrating through the first core chip,
each of the first and second core chips includes first to third nodes, the first to third nodes of the first core chip are arranged in substantially the same planar position as the first to third nodes of the second core chip, respectively,
the first node of the first core chip and the first node of the second core chip are electrically connected to each other through the first penetration electrode,
the second node of the first core chip and the third node of the second core chip are electrically connected to each other through the second penetration electrode,
the third node of the first core chip and the second node of the second core chip are electrically connected to each other through the third penetration electrode,
the test circuit supplies the core-chip test signal to the first node of the first core chip,
the control circuit of the first core chip outputs the internal signal to the second node thereof in response to the core-chip test signal supplied to the first node thereof,
the control circuit of the second core chip outputs the internal signal to the second node thereof in response to the core-chip test signal supplied to the first node thereof through the first penetration electrode, and
the test circuit generates test result signals based on the internal signal of the first core chip being output from the second node of the first core chip, and the internal signal of the second core chip being output from the third node of the first core chip.

2. The semiconductor device as claimed in claim 1, wherein
the test circuit is included in an interface chip communicating with an external terminal,
the interface chip further includes an output circuit outputting a plurality of data signals,
the test circuit activates an interface-chip test signal when the semiconductor device is in the test mode, and
the output circuit outputs either the data signals or the test result signals to outside through the external terminal according to the interface-chip test signal.

3. The semiconductor device as claimed in claim 2, wherein the data signals are supplied from either the first or second core chip.

4. The semiconductor device as claimed in claim 3, wherein
each of the first and second core chips further includes a fourth node and a core output circuit that supplies the data signals to the fourth node thereof,
the first core chip further has a fourth penetration electrode penetrating through the first core chip,
the fourth node of the first core chip and the fourth node of the second core chip are electrically connected to each other through the fourth penetration electrode, and
the output circuit receives the data signals through the fourth node of the first core chip.

5. The semiconductor device as claimed in claim 1, wherein
the test circuit is included in an interface chip having a fifth node,
the fifth node and the first node of the first core chip are electrically connected to each other, and
the test circuit supplies the core-chip test signal to the first node of the first core chip through the fifth node.

6. The semiconductor device as claimed in claim 1, wherein
the test circuit is included in an interface chip having a command decoder,
the interface chip communicates with an external terminal,
the command decoder recognizes an entry to the test mode based on a first command supplied through the external terminal.

7. The semiconductor device as claimed in claim 6, wherein the interface chip further includes a mode register that stores therein information indicating the entry to the test mode.

8. The semiconductor device as claimed in claim 6, wherein
the interface chip further includes an output circuit that outputs a plurality of data signals to outside,
the interface chip outputs the data signals to outside through the external terminal when the command decoder receives a second command, and
the test circuit activates the core-chip test signal and outputs the test result signals instead of the data signals to outside through the output circuit when the second command is supplied following the first command.

9. The semiconductor device as claimed in claim 2, wherein
the interface chip further includes a command decoder, and
the interface chip outputs the data signals to outside through the external terminal when the command decoder receives a second command, and
the output circuit outputs the test result signals instead of the data signals to outside through the external terminal in response to the supply of the second command to the command decoder when the interface-chip test signal is activated.

10. The semiconductor device as claimed in claim 1, wherein
the internal signal includes first and second internal signals,
the core-chip test signal includes first and second core-chip test signals, and
each of the control circuits of the first and second core chips outputs the first internal signal to the second node when the first core-chip test signal is activated, and outputs the second internal signal to the second node when the second core-chip test signal is activated.

11. A semiconductor device comprising:
an external terminal;
an interface chip communicating with the external terminal; and
first and second core chips being stacked to each other on the interface chip, wherein
each of the first and second core chips includes first and second penetration electrodes penetrating therethrough,
the first penetration electrode of the first core chip and the first penetration electrode of the second core chip are arranged at positions overlapped with each other as viewed from a stacking direction,
the second penetration electrode of the first core chip and the second penetration electrode of the second core chip are arranged at positions overlapped with each other as viewed from the stacking direction,
the first penetration electrode of the first core chip and the second penetration electrode of the second core chip are electrically connected to each other,
the second penetration electrode of the first core chip and the first penetration electrode of the second core chip are electrically connected to each other,
the interface chip includes a test circuit that activates a core-chip test signal when the semiconductor device is in a test mode, and an output circuit being electrically connected to the external terminal,
each of the first and second core chips outputs an internal signal that is generated in the corresponding core chip and is not output to outside in a normal mode, to the corresponding first through silicon via when the core-chip test signal is activated, and
the output circuit outputs a plurality of test result signals based on the internal signal of the first core chip being output from the first penetration electrode of the first core chip, and the internal signal of the second core chip being output from the second penetration electrode of the first core chip, to outside through the external terminal.

12. The semiconductor device as claimed in claim 11, wherein
each of the first and second core chips further includes a third penetration electrode,
the third penetration electrode of the first core chip and the third penetration electrode of the second core chip are arranged at positions overlapped with each other as viewed from the stacking direction,
the third penetration electrode of the first core chip and the third penetration electrode of the second core chip are electrically connected to each other, and
the test circuit supplies the core-chip test signal to each of the first and second core chips through the third penetration electrode of the first core chip.

13. The semiconductor device as claimed in claim 11, wherein
each of the first and second core chips further includes a fourth penetration electrode,
the fourth penetration electrode of the first core chip and the fourth penetration electrode of the second core chip are arranged at positions overlapped with each other as viewed from the stacking direction,
the fourth penetration electrode of the first core chip and the fourth penetration electrode of the second core chip are electrically connected to each other,
the test circuit activates an interface-chip test signal when the semiconductor device is in a test mode,
each of the first and second core chips outputs a data signal generated in the corresponding core chip to the corresponding fourth penetration electrode at a different timing, and
the output circuit outputs either the data signal being output from the fourth penetration electrode of the first core chip or the test result signals to outside according to the interface-chip test signal.

14. A control method of a semiconductor device comprising:
entering into a test mode in response to a first command supplied from outside;
activating a core-chip test signal in response to an entry to the test mode;
supplying the core-chip test signal from an interface chip to first nodes of first and second core chips through a penetration electrode;
supplying a plurality of internal signals from second nodes of the first and second core chips to the interface chip through a plurality of different penetration electrodes, respectively, in response to the core-chip test signal, the internal signals being not output to outside in a normal mode; and
outputting the internal signals supplied through the different penetration electrodes to outside.

15. The control method of a semiconductor device as claimed in claim 14, further comprising:
activating an interface-chip test signal in response to the first command; and
outputting either a plurality of data signals or the internal signals to outside according to the interface-chip test signal.

16. The control method of a semiconductor device as claimed in claim 15, wherein the data signals are supplied from either the first or second core chip.

17. The control method of a semiconductor device as claimed in claim 15, further comprising:
activating the core-chip test signal in response to a second command supplied following the first command; and
outputting the internal signals instead of the data signals to outside through an output circuit.

18. The control method of a semiconductor device as claimed in claim 17, further comprising:
activating the interface-chip test signal in response to the second command supplied following the first command; and
outputting the internal signals instead of the data signals to outside through the output circuit.
